(19) United States
(12) Patent Application Publication
(10) Pub. No.: US 2023/0269992 A1
(43) Pub. Date: Aug. 24, 2023

(54) DISPLAY DEVICE

(71) Applicant: LG Display Co., Ltd., Seoul (KR)

(72) Inventors: Han Seok KIM, Paju-si (KR); Mi Ra YUN, Goyang-si (KR)

(73) Assignee: LG Display Co., Ltd., Seoul (KR)

(21) Appl. No.: 18/020,494

(22) PCT Filed: Aug. 27, 2021
(86) PCT No.: PCT/KR2021/011555

§ 371 Date: Feb. 9, 2023

(30) Foreign Application Priority Data
Dec. 31, 2020 (KR) 10-2020-0189234

(51) Int. Cl. H10K 59/80; H10K 59/18; H05K 5/00

(52) U.S. Cl. CPC H10K 59/872; H05K 5/0018; H10K 59/18

(57) ABSTRACT

A display device can include a display panel, a cover shield disposed on a rear surface of the display panel, a magnetic unit disposed on the rear surface of the display panel and having a magnetic property, a first packaging member disposed on a first side surface of the display panel and the cover shield, a second packaging member disposed on a second side surface of the display panel, a third packaging member disposed on a third side surface of the display panel and the cover shield, a fourth packaging member disposed on a fourth side surface of the display panel, and a fixing plate fixing the first packaging member and the second packaging member to the magnetic unit. The first and second side surfaces of the display panel are opposite surfaces, and the third and fourth side surfaces of the display panel are opposite surfaces.

### CROSS-REFERENCE TO RELATED APPLICATIONS

This application is the National Stage filing under 35 U.S.C. 371 of International Application No. PCT/KR2021/011555, filed on Aug. 27, 2021, which claims the benefit of earlier filing date and right of priority to Korean Application No. 10-2020-0189234, filed on Dec. 31, 2020 in the Republic of Korea, where the contents of all these applications are hereby incorporated by reference herein in their entirety.

### BACKGROUND

### Field

The present disclosure relates to a display device, and more particularly, to a display device which enables safe packaging and conveying by protecting the side surfaces of a display panel.

### Discussion of the Related Art

In display devices which are used for monitors of computers, TVs, mobile phones, or the like, there are an organic light emitting display (OLED) device and the like that self-emit light, and a liquid crystal display (LCD) device and the like that require a separate light source.

The display devices are diversified in application ranges up to personal mobile devices as well as monitors of computers and TVs, and research on display devices with reduced volume and weight as well as a wide display area has been conducted.

Meanwhile, a tiling display device with a large display area can be attached on a wall surface and the like by connecting a plurality of display devices to each other to be used as a billboard and the like.

### SUMMARY OF THE DISCLOSURE

An object to be achieved by the present disclosure is to provide a display device capable of protecting the side surfaces of a display panel.

Another object to be achieved by the present disclosure is to provide a display device which enables easy packaging and opening and safe conveying.

Yet another object to be achieved by the present disclosure is to provide a display device capable of suppressing unnecessary components and the like from sticking by shielding a magnetic property of a packaging member during packaging and conveying.

Objects of the present disclosure are not limited to the above-mentioned objects, and other objects, which are not mentioned above, can be clearly understood by those skilled in the art from the following descriptions.

According to an aspect of the present invention, a display device includes a display panel, a cover shield disposed on a rear surface of the display panel, a magnetic unit disposed on the rear surface of the display panel and having a magnetic property, a first packaging member disposed on a first side surface of the display panel and the cover shield, a second packaging member disposed on a second side surface of the display panel where the second side surface is an opposite surface to the first side surface, a third packaging member disposed on a third side surface of the display panel and the cover shield, a fourth packaging member disposed on a fourth side surface of the display panel where the fourth side surface is an opposite surface to the third side surface, and a fixing plate fixing the first packaging member and the second packaging member to the magnetic unit.

Other detailed matters of the exemplary embodiments are included in the detailed description and the drawings.

According to the present disclosure, it is possible to protect the side surfaces of a display panel in which wirings and the like can be positioned.

According to the present disclosure, it is possible to easily package or open a display device by using a packaging member which protects the display device to be safely conveyed.

According to the present disclosure, it is possible to shield a magnetic property of a packaging member when packaging a display device using the packaging member to suppress unnecessary components from sticking to the packaging member with the magnetic property.

The effects according to the present disclosure are not limited to the contents exemplified above, and more various effects are included in the present specification.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a perspective view of a tiling display device according to an exemplary embodiment of the present disclosure.

FIGS. 2 and 3 are exploded perspective views of a display device according to an exemplary embodiment of the present disclosure.

FIG. 4 is a schematic perspective view for describing an assembling process of the display device according to an exemplary embodiment of the present disclosure.

FIG. 5 is an enlarged diagram of area A of FIG. 4.

FIG. 6 is a schematic perspective view for describing an assembling process of the display device according to an exemplary embodiment of the present disclosure.

FIG. 7 is a cross-sectional view of FIG. 6 taken along line VII-VII′.

FIGS. 8 to 10 are a schematic cross-sectional view (FIG. 8) and a perspective view (FIGS. 9 and 10) for describing a disassembling process of the display device according to an exemplary embodiment of the present disclosure.

FIG. 11 is a plan view of a first state of a display device according to another exemplary embodiment of the present disclosure.

FIG. 12 is a rear view of a first state of the display device according to another exemplary embodiment of the present disclosure.

FIG. 13 is a perspective view of a first state of the display device according to another exemplary embodiment of the present disclosure.

FIG. 14 is a cross-sectional view of FIG. 12 taken along line XIV-XIV′.

FIG. 15 is a cross-sectional view for describing a change from a first state to a second state of the display device according to another exemplary embodiment of the present disclosure.

FIG. 16 is a rear view of the second state of the display device according to another exemplary embodiment of the present disclosure.

FIG. 17 is a perspective view of the second state of the display device according to another exemplary embodiment of the present disclosure.

FIG. 18 is a cross-sectional view of the second state of the display device according to another exemplary embodiment of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as ‘including’, ‘having’, etc. used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘under’, ‘next’, one or more parts can be positioned between the two parts unless the terms are used with the term ‘immediately’ or ‘directly’.

When an element or layer is disposed “on” another element or layer, another layer or another element (or multiple layers/elements)can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

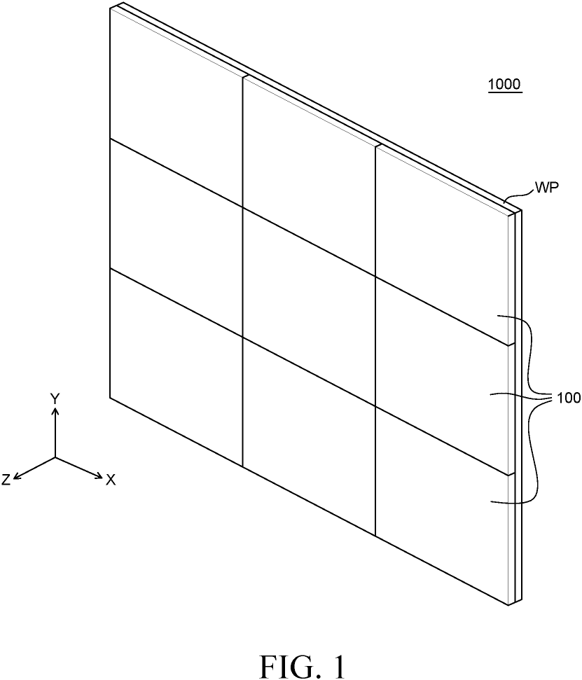

FIG. 1 is a perspective view of a tiling display device according to an exemplary embodiment of the present disclosure.

Referring to FIG. 1, a tiling display device 1000 according to an exemplary embodiment of the present disclosure is achieved by connecting a plurality of display devices 100 to each other according to an exemplary embodiment of the present disclosure.

Referring to FIG. 1, the tiling display device 1000 according to an exemplary embodiment of the present disclosure includes a plurality of display devices 100 and a wall surface portion WP. The tiling display device 1000 includes the plurality of display devices 100 to enlarge a display area in which an image is displayed.

Each of the plurality of display devices 100 is attached to the wall surface portion WP to be aligned like a single display device 100. For example, the plurality of display devices 100 is attached to the wall surface portion WP in a tile form to implement the tiling display device 1000.

At this time, the plurality of display devices 100 can be attached to each other as close as possible so that intervals between the plurality of display devices 100 are constant and minimized so that the plurality of display devices 100 looks like one display device. For example, the plurality of display devices 100 is precisely aligned to be attached to the wall surface portion WP, thereby minimizing a boundary area in which an image is not displayed.

At this time, each of the plurality of display devices 100 can be aligned in an X-axis direction, a Y-axis direction, and a Z-axis direction to be attached to the wall surface portion WP. When the plurality of display devices 100 is aligned in the X-axis direction, a left edge and a right edge of the plurality of display devices 100 disposed in the same column can be aligned to be disposed in a straight line, respectively. In addition, when the plurality of display devices 100 is aligned in the Y-axis direction, an upper edge and a lower edge of the plurality of display devices 100 disposed in the same row can be aligned to be disposed in a straight line, respectively. In addition, when the plurality of display devices 100 is aligned in the Z-axis direction, all front surfaces of the plurality of display devices 100 can be aligned to be disposed on one plane so as to remove steps between the plurality of display devices 100.

Meanwhile, since the tiling display device 1000 has an extra-large size, it is difficult to convey the tiling display device 1000 to an installation place while connecting the plurality of display devices 100 to each other. Thus, after the plurality of display devices 100 is conveyed to the installation place, the plurality of display devices 100 can be assembled to the tiling display device 1000 in the installation place.

In the display devices 100 according to an exemplary embodiment of the present disclosure, a packaging member for protecting display panels 100 can be assembled when conveying the display devices 100. At the installation place, the packaging member can be separated from the display devices 100 and the display devices 100 safely conveyed can be assembled to the tiling display device 1000. Thus, when conveying the plurality of display devices 100 for tiling, it is possible to suppress the display panels 100 from being impacted and the display devices 100 from being damaged.

Further, the packaging member for packing the display devices 100 when conveying the display devices 100 can be fixed to the display devices 100 using a magnetic unit having a magnetic property to be easily assembled. Thus, the display devices 100 can be easily packaged, and also conveniently separated.

However, when the display devices 100 are assembled by applying a magnetic to the packaging member, there can be a limitation that unnecessary components and the like can stick to the magnetic units of the display devices 100. In addition, there can be a limitation that a damage to the display devices 100 can be caused by the stuck components, a load can occur in the conveying process to remove the stuck components to the display devices 100, or the like.

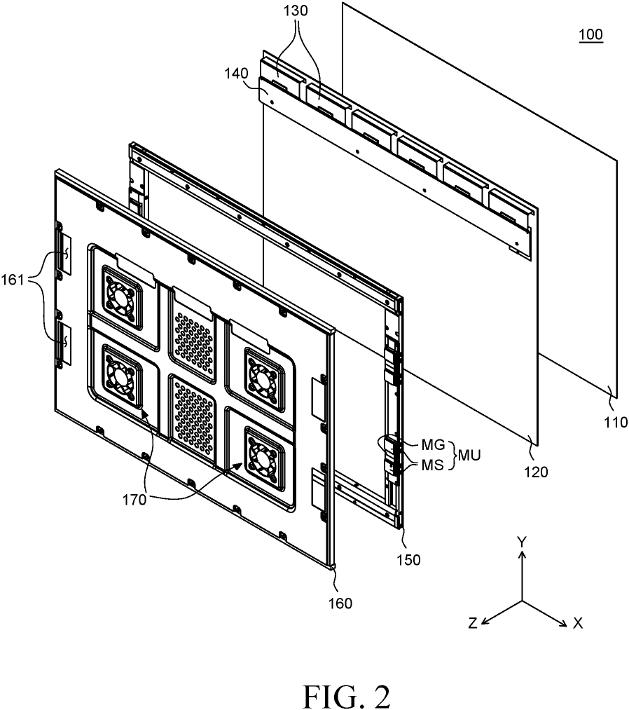

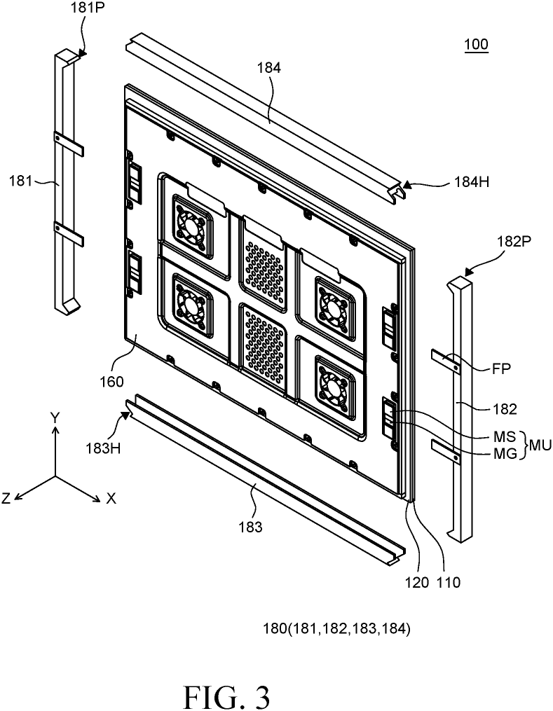

Accordingly, the display device 100 according to an exemplary embodiment of the present disclosure is configured to be easily packaged and separated by using a magnet, but is configured to block a magnetic field line from being removed to the outside of the display device 100 after packaging a display panel 120 and a packaging member 180 (e.g., FIGS. 2 and 3 and other figures). Therefore, it is possible to suppress the unnecessary components from sticking to the display device 100.

Specifically, the display device 100 according to an exemplary embodiment of the present disclosure can include a fixing plate FP (e.g., FIG. 3 and other figures) made of a ferromagnetic material. After the fixing plate FP is attached to a magnetic unit MU disposed on the display panel 120 side, the display device 100 can be configured to block a magnetic field line from being removed to the outside of the fixing plate FP by the feature of the ferromagnetic material shielding a magnetic force.

Hereinafter, the display device 100 according to an exemplary embodiment of the present disclosure will be described in detail with reference to FIGS. 2 and 3.

FIGS. 2 and 3 are exploded perspective views of the display device according to an exemplary embodiment of the present disclosure. Specifically, FIG. 2 is an exploded perspective view of the display device 100 viewed from a rear surface of the display device 100 and FIG. 3 is an exploded perspective view of the display device 100 in which the packaging member is separated from the display device 100. In FIG. 2, for the convenience of the description, the packaging member has been omitted.

Referring to FIG. 2, the display device 100 includes a protective plate 110, a display panel 120, a plurality of flexible films 130, a printed circuit board 140, a frame 150, a cover shield 160, a heat dissipation fan 170, and a plurality of magnetic units MU.

First, the display panel 120 is a configuration for displaying an image to the user. The display panel 120 can be disposed with, for example, a display element, and circuits, lines, components, and the like for driving the display element. The display element can be defined differently depending on a type of display panel 120, and for example, when the display panel 120 is an organic light emitting display panel, the display element can be an organic light emitting diode including an anode, an organic emission layer, and a cathode. For example, if the display panel 120 is an inorganic light emitting display panel, the display element can be a light emitting diode LED or a micro LED including an n-type semiconductor layer, a p-type semiconductor layer, and an emission layer. However, it is not limited thereto, and the display element of the display panel 120 can be variously configured.

The plurality of flexible films 130 is bonded to the rear surface of the display panel 120. The flexible film 130 can be electrically connected with the display panel 120 as a film for supplying a signal to a display element and a circuit unit by disposing various components in a flexible base film. The plurality of flexible films 130 can supply a power supply voltage, a data voltage, and the like to the display panel 120. On the other hand, in FIG. 2, it has been illustrated that the number of the plurality of flexible films 130 is 6 and the plurality of flexible films 130 is bonded to a long side of the display panel 120. However, the number and disposition of the plurality of flexible films 130 can be variously changed according to a design, but are not limited thereto.

Driving integrated circuits (ICs) such as a gate driver IC and a data driver IC can be disposed in the plurality of flexible films 130. The driving IC is a component that processes data for displaying an image and a driving signal for processing the data. The driving IC can be disposed by a method such as chip on glass COG, chip on film COF, and tape carrier package TCP, in accordance with a mounting method. However, for the convenience of the description, it has been described as the chip on film method in which the driving ICs are mounted on the plurality of flexible films 130, but is not limited thereto.

The printed circuit board 140 is electrically connected with the plurality of flexible films 130. The printed circuit board 140 is a component that supplies a signal to the driving IC. The printed circuit board 140 can be disposed with various components for supplying various signals such as a driving signal and a data signal to the driving ICs. On the other hand, in FIG. 2, one printed circuit board 140 has been illustrated, but the number of the printed circuit boards 140 can be variously changed according to a design, and is not limited thereto.

The frame 150 is disposed on the rear surface of the display panel 120. The frame 150 can support and protect the display panel 120 on the rear surface of the display panel 120. The frame 150 can be made of a rigid material, and for example, can be made of a metal material such as aluminum (Al), copper (Cu), zinc (Zn), silver (Ag), gold (Au), iron (Fe), steel use stainless (SUS) or invar, or a material such as plastic.

The frame 150 can have a shape corresponding to an edge of the display panel 120. For example, the frame 150 can be formed in a frame shape corresponding to the edge of the display panel 120. The frame 150 can support the edge of the display panel 120 to allow the display panel 120 to be maintained in a flat state. However, the frame 150 can also be formed in the same shape as the planar shape of the display panel 120 instead of the frame shape, and the shape of the frame 150 is not limited thereto so long as the frame 150 can support the display panel 120.

A plurality of magnetic units MU is disposed on the rear surface of the display panel 120. The plurality of magnetic units MU can be fixed to the rear surface of the frame 150 on the rear surface of the display panel 120. The plurality of magnetic units MU is a component which is disposed on the rear surfaces of the display panel 120 and the frame 150 to attach the display device 100 to the wall surface portion WP.

Each of the plurality of magnetic units MU can include a panel magnet MG and a panel ferromagnetic material MS.

For example, the panel magnet MG can be a bar-shaped magnet composed of one N pole and one S pole, but is not limited thereto. At this time, the panel magnet MG can be fixed to the frame 150 using an adhesive member or a separate fastening member, but is not limited thereto.

The panel ferromagnetic material MS can be fixed to the rear surface of the frame 150 on the rear surface of the display panel 120. The panel ferromagnetic materials MS can be disposed on both side surfaces of the panel magnet MG. Each panel magnet MG can be disposed between two panel ferromagnetic materials MS. For example, one panel ferromagnetic material MS of the plurality of panel ferromagnetic materials MS can be in contact with an N pole of the panel magnet MG and the other panel ferromagnetic material MS can be in contact with an S pole of the panel magnet MG. One panel magnet MG can be disposed between the two panel ferromagnetic materials MS. The plurality of panel ferromagnetic materials MS can be made of a ferromagnetic material, for example, steel, but is not limited thereto.

The display device 100 can be attached to the wall surface portion WP using the magnetic unit MU. For example, when the display device 100 is in contact with the wall surface portion WP, magnetic field lines are induced among the wall surface portion WP, the panel magnet MG, and the panel ferromagnetic material MS, so that the display device 100 can be fixed to the wall surface portion WP. At this time, the plurality of panel ferromagnetic materials MS will be omitted, and the display panel 100 can be attached to the wall surface portion WP by only the plurality of panel magnets MG. Meanwhile, the method of attaching the display device 100 to the wall surface portion WP by using the plurality of panel magnets MG and the plurality of panel ferromagnetic materials MS is exemplified. However, other fastening members can also be disposed instead of the plurality of panel magnets MG and the plurality of panel ferromagnetic materials MS, but it is not limited thereto.

Referring to FIG. 2, the cover shield 160 is disposed on the rear surface of the frame 150. The cover shield 160 can cover the plurality of flexible films 130 and the printed circuit board 140 on the rear surface of the frame 150. Specifically, the plurality of flexible films 130 is bonded to the rear surface of the display panel 120. At this time, the plurality of flexible films 130 and the printed circuit board 140 are not disposed between the display panel 120 and the frame 150, but can be disposed to cover the frame 150. The plurality of flexible films 130 can be easily bent as a film in which various components are disposed on the flexible base film as described above. Accordingly, the plurality of flexible films 130 is bent to cover the frame 150, so that the plurality of flexible films 130 and the printed circuit board 140 can be disposed on the display panel 120 and the frame 150.

The cover shield 160 is disposed to cover the display panel 120, the plurality of flexible films 130, the printed circuit board 140, and the frame 150. Specifically, since the frame 150 does not cover the plurality of flexible films 130 and the printed circuit board 140, it can be difficult to protect the plurality of flexible films 130 and the printed circuit board 140 from an external impact. Therefore, the cover shield 160 can be disposed on the rear surface of the frame 150 to protect the plurality of flexible films 130 and the printed circuit board 140. The cover shield 160 is disposed to cover the display panel 120, the plurality of flexible films 130, the printed circuit board 140, and the frame 150 to protect other components of the display device 100, particularly, the plurality of flexible films 130 and the printed circuit board 140.

The cover shield 160 includes a plurality of first holes 161 to expose the plurality of panel magnets MG and the plurality of panel ferromagnetic materials MS.

Referring to FIG. 2, the plurality of first holes 161 can be holes which expose the plurality of panel magnets MG and the plurality of panel ferromagnetic materials MS which are magnetic units MU fixed to the rear surface of the frame 150. The plurality of panel magnets MG and the plurality of panel ferromagnetic materials MS exposed through the plurality of first holes 161 can be in closer contact with the wall surface portion WP and the intensity of the magnetic field lines can be increased. If the plurality of panel magnets MG and the plurality of panel ferromagnetic materials MS are covered with the cover shield 160, the cover shield 160 can weaken the intensity of the magnetic field lines by increasing intervals between the wall surface portion WP and the plurality of panel magnets MG and the plurality of panel ferromagnetic materials MS and the display device 100 can be detached from the wall surface portion WP. Thus, the plurality of first holes 161 is disposed so that the plurality of panel magnets MG and the plurality of panel ferromagnetic materials MS are disposed adjacent to the wall surface portion WP to firmly attach the display device 100 to the wall surface portion WP.

Meanwhile, the cover shield 160 can include a plurality of second holes for heat dissipation. The plurality of second holes can be disposed at least to overlap the flexible films 130 and the printed circuit board 140. The plurality of second holes can be disposed at least to overlap the flexible films 130 and the printed circuit board 140 extremely heated to effectively emit the heat generated in the display device 100.

The heat dissipation fan 170 can be disposed on the rear surface of the display panel 120. The heat dissipation fan 170 can circulate air between the cover shield 160 and the display panel 120 to emit the heat generated when driving the display device 100. The heat of the display device 100 can be emitted by convecting the air in the display device 100 by using the heat dissipation fan 170. At this time, the air can be introduced or emitted through the heat dissipation fan 170 and the plurality of second holes of the cover shield 160. On the other hand, in FIG. 2, it has been illustrated that four heat dissipation fans 170 are disposed, but the heat dissipation fans 170 can be omitted according to a design, and the number and disposition of the heat dissipation fans 170 are not limited thereto.

The protective plate 110 is disposed to cover the front surface of the display panel 120. The protective plate 110 is disposed to cover the display panel 120 to protect the display panel 120 from external impact, moisture, heat, or the like. The protective plate 110 can be made of a material with impact resistance and light transmittance. For example, the protective plate 110 can be a substrate made of glass, or a thin film made of a plastic material such as polycarbonate (PC), polyimide (PI), polymethylmethacrylate (PMMA), and polyethylene terephthalate (PET), but is not limited thereto.

The plurality of packaging members 180 can be disposed on the side surfaces of the display panel 120 and the cover shield 160 to protect the display panel 120 during a conveying of the display device 100. The packaging member 180 can include a first packaging member 181, a second packaging member 182, a third packaging member 183, and a fourth packaging member 184.

The first packaging member 181 can be disposed on a first side surface of the display panel 120 and the cover shield 160. The second packaging member 182 can be disposed on a second side surface of the display panel 120 and the cover shield 160, which is an opposite surface to the first side surface of the display panel 120. At this time, the first side surface and the second side surface can correspond to a left side surface and a right side surface of the display panel 120 and the cover shield 160, but are not limited thereto. The third packaging member 183 can be disposed on a third side surface of the display panel 120 and the cover shield 160. The fourth packaging member 184 can be disposed on a fourth side surface of the display panel 120 and the cover shield 160, which is an opposite surface to the third side surface of the display penal 120. At this time, the third side surface and the fourth side surface of the display panel can correspond respectively to an upper side surface and a lower side surface (or vice versa) of the display panel 120 and the cover shield 160, but are not limited thereto. Thus, it has been illustrated that on a plane, the first side surface and the second side surface correspond to short sides, and the third side surface and the fourth side surface correspond to long sides, but it is not limited thereto and can be variously changed according to a design.

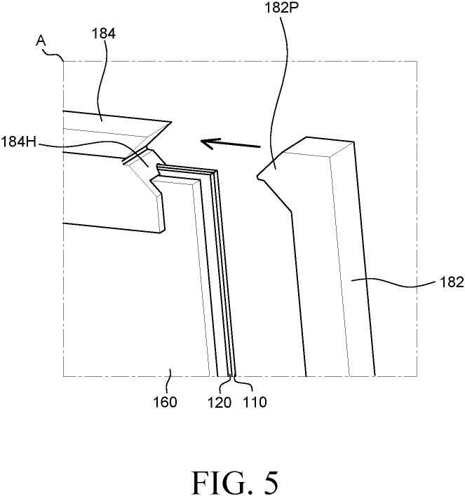

The side surfaces of the first packaging member 181 and the second packaging member 182 include inclined protrusions 181P and 182P, and the side surfaces of the third packaging member 183 and the fourth packaging member 184 can have inclined surfaces 183H and 184H corresponding to the protrusions 181P and 182P. The side surfaces of the first packaging member 181, the second packaging member 182, the third packaging member 183, and the fourth packaging member 184 will be described in more detail with reference to FIG. 5.

The fixing plate FP can fix the first packaging member 181 and the second packaging member 182 to the magnetic unit MU. The fixing plate FP can be fixed to the first packaging member 181 and the second packaging member 182 through a mechanical configuration such as bolts. Further, the fixing plate FP can be fixed to the magnetic unit MU by the magnetic property of the magnetic unit MU. As described above, as the fixing plate FP is fixed to the first packaging member 181 and the second packaging member 182 and the magnetic unit MU, the fixing plate FP can fix the first packaging member 181 and the second packaging member 182 to the magnetic unit MU. At this time, the fixing plate FP can be made of a ferromagnetic material to fix to the magnetic unit MU by the magnetic property of the magnetic unit MU, for example, steel, but it is not limited thereto.

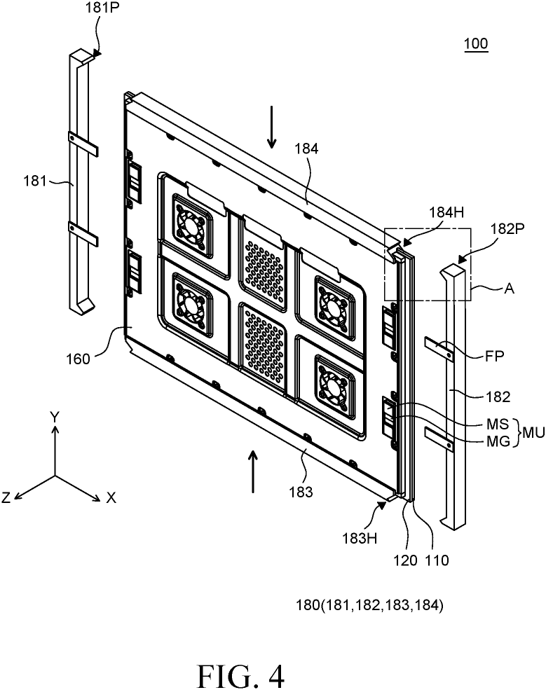

Hereinafter, an assembling process of the display device 100 according to an exemplary embodiment of the present disclosure will be described with reference to FIGS. 4 to 7.

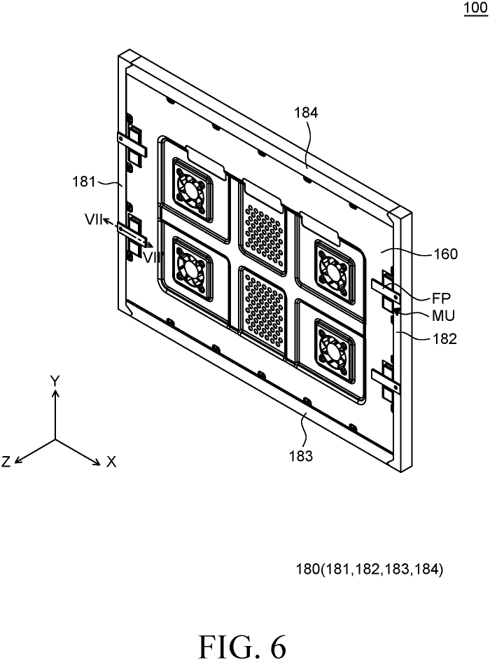

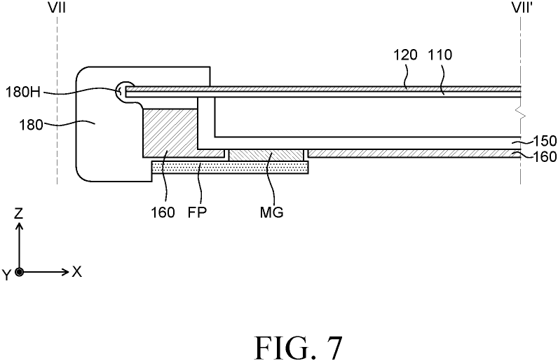

FIG. 4 is a schematic perspective view for describing an assembling process of a display device according to an exemplary embodiment of the present disclosure. FIG. 5 is an enlarged diagram of area A of FIG. 4. FIG. 6 is a schematic perspective view for describing an assembling process of a display device according to an exemplary embodiment of the present disclosure. FIG. 7 is a cross-sectional view of FIG. 6 taken along line VII-VII’.

First, referring to FIG. 4, the third packaging member 183 and the fourth packaging member 184 are assembled on the display panel 120 side. Specifically, the protective plate 110, the display panel 120, the frame 150, and the cover shield 160 are inserted to the third packaging member 183 and the fourth packaging member 184, and the third packaging member 183 and the fourth packaging member 184 can be assembled on the display panel 120 side. At this time, the third packaging member 183 and the fourth packaging member 184 can include grooves 180H to which the display panel 120 and the protective plate 110 are inserted. A more detailed description thereof will be described below with reference to FIG. 7.

Next, referring to FIGS. 5 and 6, the first packaging member 181 and the second packaging member 182 are assembled on the display panel 120 side. Specifically, the protective plate 110, the display panel 120, the frame 150, and the cover shield 160 are inserted to the first packaging member 181 and the second packaging member 182, and the first packaging member 181 and the second packaging member 182 can be assembled on the display panel 120 side. At this time, the first packaging member 181 and the second packaging member 182 can include grooves 180H (e.g., see FIG. 7) to which the display panel 120 and the protective plate 110 are inserted. A more detailed description thereof will be described below with reference to FIG. 7.

Referring to FIG. 5, the side surfaces of the first packaging member 181 and the second packaging member 182 include the inclined protrusions 181P and 182P, and the side surfaces of the third packaging member 183 and the fourth packaging member 184 can have the inclined surfaces 183H and 184H corresponding respectively to the protrusions 181P and 182P.

Referring to FIG. 6, the inclined surfaces 183H and 184H of the third packaging member 183 and the fourth packaging member 184 and the protrusions 181P and 182P of the first packaging member 181 and the second packaging member 182 are fitted and fastened with each other, so that the packaging member 180 can be assembled outside the display panel 120. Specifically, the inclined surface 183H of the third packaging member 183 can be fitted and fastened with the protrusions 181P and 182P of the first packaging member 181 and the second packaging member 182. The inclined surface 184H of the fourth packaging member 184 can be fitted and fastened with the protrusions 181P and 182P of the first packaging member 181 and the second packaging member 182. As a result, when the first packaging member 181 and the second packaging member 182 are fixed to the magnetic unit MU, the third packaging member 183 and the fourth packaging member 184 can be fixed without detachment by the protrusion 181P of the first packaging member 181 and the protrusion 182P of the second packaging member 182.

Referring to FIG. 7, the side surfaces of the display panel 120 can be spaced apart from the first packaging member 181, the second packaging member 182, the third packaging member 183 and the fourth packaging member 184. For example, the first packaging member 181, the second packaging member 182, the third packaging member 183 and the fourth packaging member 184 can have grooves 180H at positions corresponding to the side surfaces of the display panel 120. At this time, the diameter of each groove 180H can be larger than the thickness of the display panel 120. The side surfaces of the display panel 120 are spaced apart from the first packaging member 181, the second packaging member 182, the third packaging member 183 and the fourth packaging member 184 so as not to be in direct contact with the packaging member 180 and to be protected from the external impact, so that the display panel 120 can be further stably protected during conveying.

Meanwhile, the magnetic unit MU which is disposed on the rear surface of the frame 150 and exposed to the outside can be in contact with the fixing plate FP disposed on the packaging member 180 as the packaging member 180 is assembled to the display panel 120. For example, referring to FIG. 7, the fixing plate FP disposed on the first packaging member 181 can be in contact with the magnetic unit MU and the fixing plate FP can be fixed to the magnetic unit MU by the magnetic property of the magnetic unit MU. As a result, the fixing plate FP can fix the first packaging member 181 and the magnetic unit MU, and in the same principle, the second packaging member 182 can also be fixed to the magnetic unit MU by the fixing plate FP.

In addition, as described above, the inclined surface 183H of the third packaging member 183 can be fitted and fastened with the protrusions 181P and 182P of the first packaging member 181 and the second packaging member 182. The inclined surface 184H of the fourth packaging member 184 can be fitted and fastened with the protrusions 181P and 182P of the first packaging member 181 and the second packaging member 182. As a result, when the first packaging member 181 and the second packaging member 182 are fixed to the magnetic unit MU by the fixing plate FP, the third packaging member 183 and the fourth packaging member 184 can be fixed without detachment by the protrusion 181P of the first packaging member 181 and the protrusions 181P and 182P of the second packaging member 182.

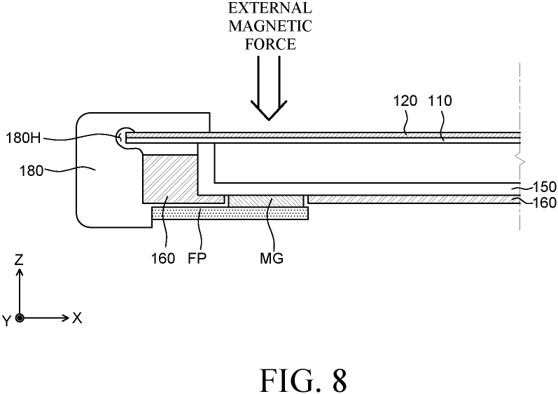

Hereinafter, a disassembling process of the display device 100 according to an exemplary embodiment of the present disclosure will be described with reference to FIGS. 8 to 10.

FIGS. 8 to 10 are a schematic cross-sectional view and a perspective view for describing a disassembling process of the display device according to an exemplary embodiment of the present disclosure.

First, referring to FIG. 8, the fixing plate FP fixed to the magnetic unit MU can be detached from the magnetic unit MU by a magnetic force applied from the outside. Since the magnetic force between the fixing plate FP and the magnetic unit MU is weakened as the magnetic force is applied to the outside, the fixing plate FP can be easily detached from the magnetic unit MU. At this time, the external magnetic force can be caused by the magnet and the ferromagnetic material included in an attachment device used for tiling the display device 100, but is not limited thereto.

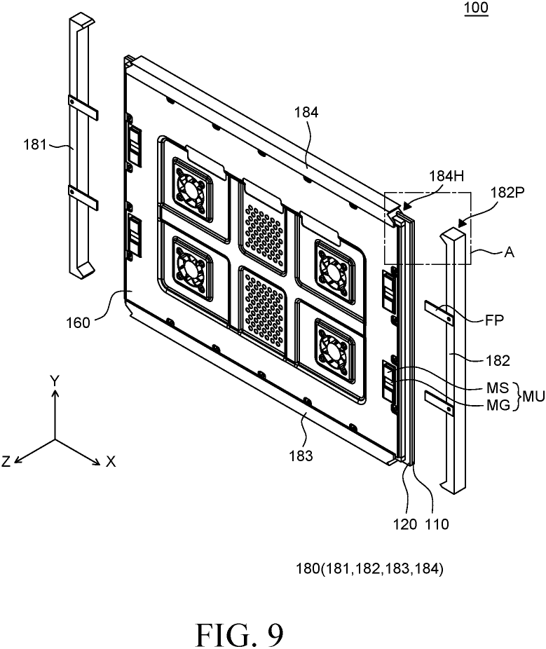

Subsequently, referring to FIG. 9, as the magnetic force between the fixing plate FP and the magnetic unit MU is weakened, the first packaging member 181 and the second packaging member 182 disposed with the fixing plates FP can be separated from the cover shield 160 side.

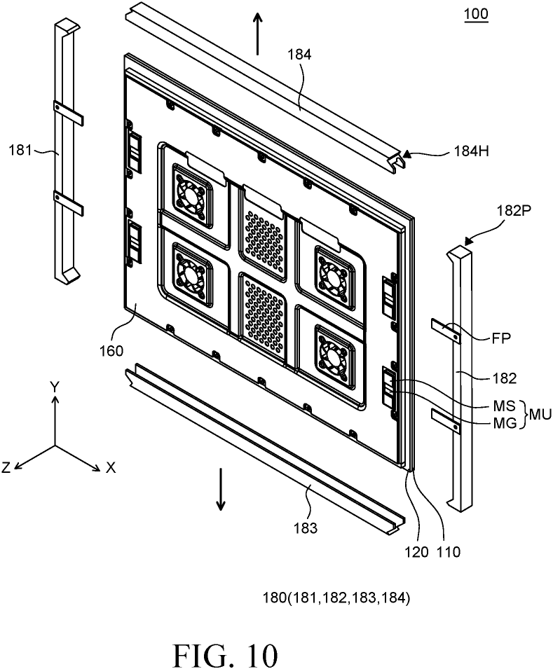

Next, referring to FIG. 10, as the first packaging member 181 and the second packaging member 182 are separated from each other, the third packaging member 183 and the fourth packaging member 184 can be separated from each other. For example, in the third packaging member 183 and the fourth packaging member 184 fitted and fastened with the first packaging member 181 and the second packaging member 182, as the first packaging member 181 and the second packaging member 182 are separated from each other, the third packaging member 183 and the fourth packaging member 184 can also be separated from each other.

In the display device 100 according to an exemplary embodiment of the present disclosure, the packaging member 180 for protecting the display panel 120 can be assembled when conveying the display device. At an installation place for installing the display devices 100 to the tiling display device 100, the packaging member 180 can be separated from the display device 100 and the safely conveyed display devices 100 can be assembled to the tiling display device 100. Accordingly, in the display device 100 according to an exemplary embodiment of the present disclosure, when conveying the plurality of display devices 100 for tiling, it is possible to suppress the display device 100 from being damaged due to an impact applied to the display panel 120.

In addition, in the display device 100 according to an exemplary embodiment of the present disclosure, the packaging member 180 for packaging the display device 100 can be easily separated during conveying of the display device 100. Specifically, since the fixing plate FP is fixed using the magnetic unit MU, the fixing plate FP can be easily separated from the magnetic unit MU by applying the external magnetic force to the magnetic unit MU and the tiling operation and the separating operation can be performed at the same time.

Further, in the display device 100 according to an exemplary embodiment of the present disclosure, since the fixing plate FP is disposed to cover the magnetic unit MU, limitations that unnecessary components and the like can stick to the magnetic unit MU, a damage to the display device 100 may be caused by the stuck components, a load can occur in the conveying process to remove the stuck components to the display device 100, or the like can be solved.

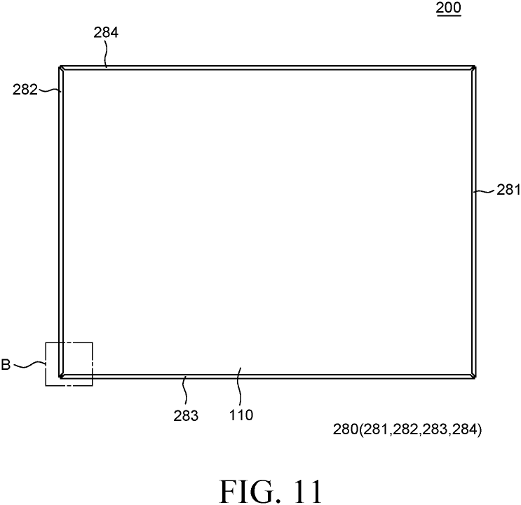

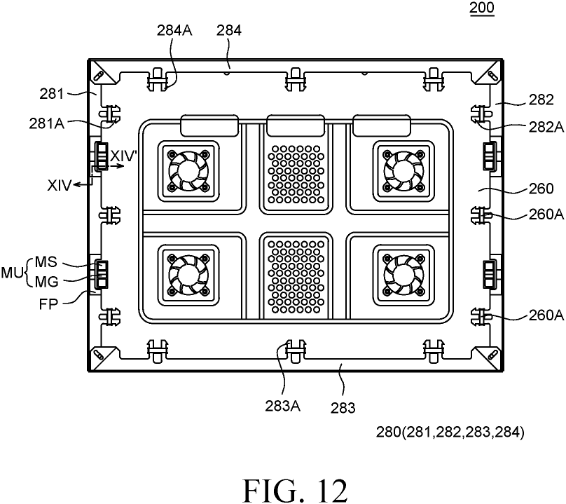

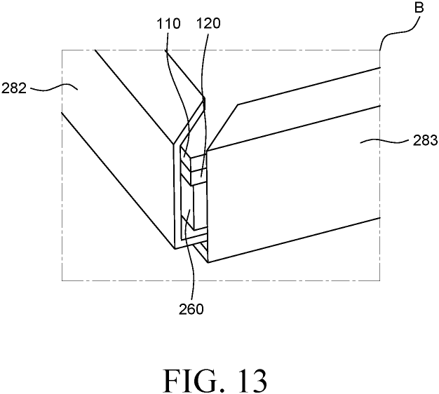

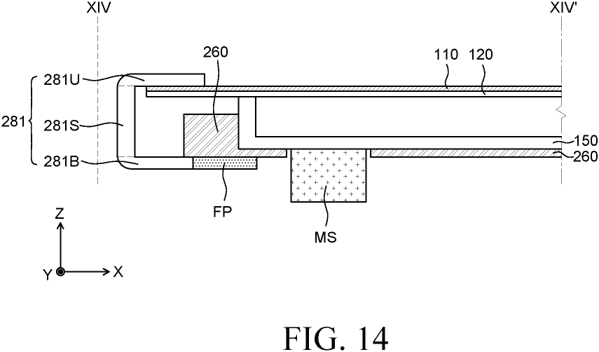

FIG. 11 is a plan view of a first state of the display device according to another exemplary embodiment of the present disclosure. FIG. 12 is a rear view of a first state of the display device according to another exemplary embodiment of the present disclosure. FIG. 13 is a perspective view of a first state of the display device according to another exemplary embodiment of the present disclosure. FIG. 14 is a cross-sectional view of FIG. 11 taken along line XIV-XIV′.

When the display device of FIGS. 11 to 14 are compared with the display device of FIGS. 1 to 10, only the plurality of packaging members and fixing plates are different from each other, and other components are substantially the same as each other, and thus, the duplicated description will be omitted or may be provided briefly.

A display device 200 according to another exemplary embodiment of the present disclosure can be in one of a first state and a second state. The first state can be a state in which a first packaging member 281, a second packaging member 282, a third packaging member 283, and a fourth packaging member 284 as a plurality of packaging members 280 cover the side surfaces of a display panel 120. The second state can be a state in which the first packaging member 281, the second packaging member 282, the third packaging member 283, and the fourth packaging member 284 are disposed below the display panel 120.

First, referring to FIGS. 11 to 14, when the display device 200 is in the first state, the first packaging member 281, the second packaging member 282, the third packaging member 283, and the fourth packaging member 284 can cover the side surfaces of the display panel 120. At this time, the first packaging member 281, the second packaging member 282, the third packaging member 283, and the fourth packaging member 284 can be spaced apart from the side surfaces of the display panel 120.

In order to describe a more detailed disposition relation of the first packaging member 281, the second packaging member 282, the third packaging member 283, and the fourth packaging member 284, referring to FIG. 14, the first packaging member 281 includes an upper plate 281U, a side plate 281S, and a lower plate 281B. The upper plate 281U can be disposed on the upper surface of the display panel 120 in the first state. As a result, the upper plate 281U can cover a part of the upper surface of the display panel 120. The side plate 281S can be disposed so as to surround the side surfaces of the display panel 120 and a cover shield 260 in the first state. At this time, the side plate 281S can be spaced apart from the side surfaces of the display panel 120 and the cover shield 260. The lower plate 281B can be disposed below the lower surface of the cover shield 260 in the first state. FIG. 14 illustrates a cross section for the first packaging member 281, but the second packaging member 282, the third packaging member 283, and the fourth packaging member 284 can also include upper plates, side plates, and lower plates in the same disposition as the first packaging member 281.

Referring to FIGS. 11 to 13, the plurality of packaging members 280 can be spaced apart from each other at edges of the display panel 120 and the cover shield 260. For example, the first packaging member 281, the second packaging member 282, the third packaging member 283, and the fourth packaging member 284 can be spaced apart from each other without being in contact with each other on the edges of the display panel 120 and the cover shield 260.

On the other hand, referring to FIG. 12, an additional fastening structure can be applied for fastening the plurality of packaging members 280 and the cover shield 260. For example, the plurality of packaging members 280 can include first fastening portions 281A, 282A, 283A, and 284A, which can be fastened with the cover shield 260, respectively. At this time, the first fastening portions 281A, 282A, 283A, and 284A can have, for example, hook shapes, but are not limited thereto. The cover shield 260 can include a second fastening portion 260A in which the plurality of packaging members 280 can be fastened. The second fastening portion 260A can provide a space into which the first fastening portions 281A, 282A, 283A, and 284A are inserted.

The fixing plate FP can be disposed in lower plates 281B, 282B, 283B, and 284B. The fixing plate FP can fix the first packaging member 281 and the second packaging member 282 to the magnetic unit MU. The fixing plate FP can be fixed to the first packaging member 281 and the second packaging member 282 through a configuration such as an adhesive layer, etc. Further, since the fixing plate FP is spaced apart from the magnetic unit MU, but adjacent to the magnetic unit MU, the fixing plate FP can be fixed to the magnetic unit MU by the magnetic property of the magnetic unit MU. As described above, as the fixing plate FP is fixed to the first packaging member 281 and the second packaging member 282 and the magnetic unit MU, the fixing plate FP can fix the first packaging member 281 and the second packaging member 282 to the magnetic unit MU. At this time, the fixing plate FP can be made of a ferromagnetic material to be fixed to the magnetic unit MU by the magnetic property of the magnetic unit MU, for example, steel, but it is not limited thereto.

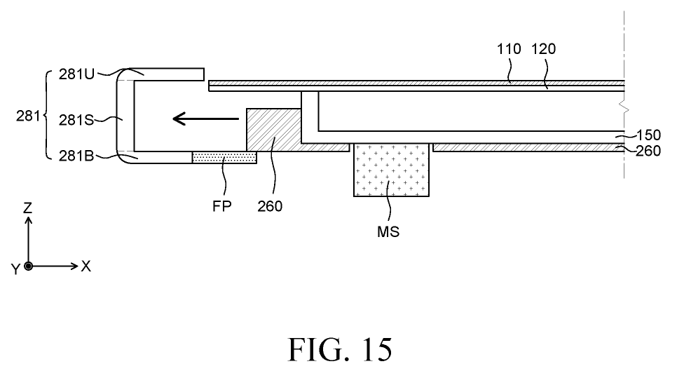

FIG. 15 is a cross-sectional view for describing a change from a first state to a second state of the display device according to another exemplary embodiment of the present disclosure.

Referring to FIG. 15, the fixing plate FP fixed to the magnetic unit MU can be detached from the magnetic unit MU by a magnetic force applied from the outside. Since the magnetic force between the fixing plate FP and the magnetic unit MU is weakened as the magnetic force is applied to the outside, the fixing plate FP can be easily detached from the magnetic unit MU. At this time, the external magnetic force can be generated by the magnet and the ferromagnetic material included in an attachment device used for tiling the display device 200, but is not limited thereto.

After the magnetic force is applied from the outside, the plurality of packaging members 280 can be moved in an outer direction of the display panel 120 by a user. Thereafter, the user can move the plurality of packaging members 280 in a lower direction, for example, from the display panel 120 to the cover shield 260. Thereafter, the user can move the plurality of packaging members 280 in an inner direction of the display panel 120 so that the upper plates of the plurality of packaging members 280 can be inserted between the display panel 120 and the cover shield 260. Thus, the display device 200 can be changed from the first state to the second state.

FIG. 15 illustrates a cross section for the first packaging member 281, but the second packaging member 282, the third packaging member 283, and the fourth packaging member 284 can be moved in the same manner as the first packaging member 281.

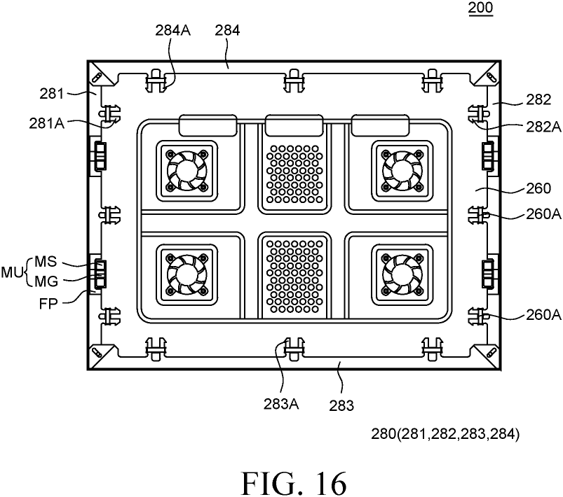

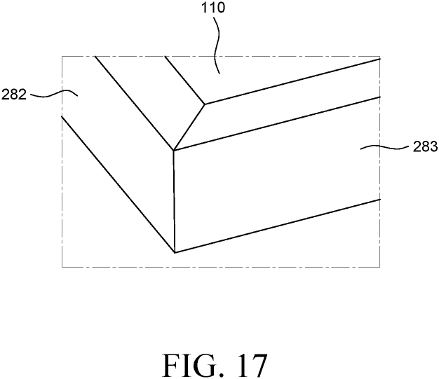

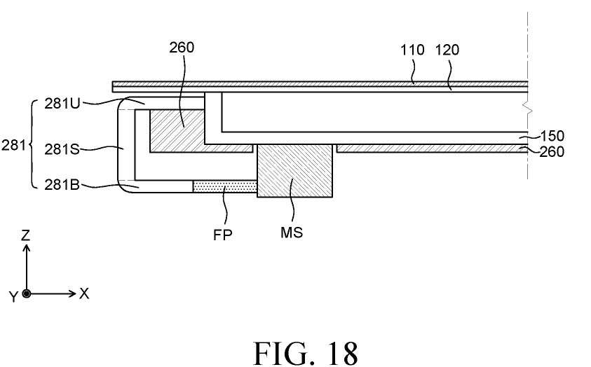

FIG. 16 is a rear view of a second state of the display device according to another exemplary embodiment of the present disclosure. FIG. 17 is a perspective view of the second state of the display device according to another exemplary embodiment of the present disclosure. FIG. 18 is a cross-sectional view of the second state of the display device according to another exemplary embodiment of the present disclosure.

Referring to FIGS. 16 to 18, when the display device 200 is in the second state, the first packaging member 281, the second packaging member 282, the third packaging member 283, and the fourth packaging member 284 can be disposed below the display panel 120.

In order to describe a more detailed disposition relationship of the first packaging member 281, the second packaging member 282, the third packaging member 283, and the fourth packaging member 284, referring to FIG. 18, the upper plate 281U of the first packaging member 281 can be disposed between the display panel 120 and the cover shield 260 in the second state. As a result, the upper plate 281U may not be viewed from the upper surface side of the display panel 120. The side plate 281S can be disposed so as to surround the side surface of the cover shield 260 below the display panel 120 in the second state. Specifically, the side plate 281S can be disposed inside the side surface of the display panel 120 or can be disposed on the same plane. As a result, the side plate 281S may also not be viewed from the upper surface side of the display panel 120. The lower plate 281B can be disposed below the lower surface of the cover shield 260 in the second state. FIG. 18 illustrates a cross section for the first packaging member 281, but the second packaging member 282, the third packaging member 283, and the fourth packaging member 284 can also include upper plates, side plates, and lower plates in the same disposition as the first packaging member 281.

Referring to FIGS. 16 to 18, the plurality of packaging members 280 can be in contact with each other at edges of the display panel 120 and the cover shield 260. For example, the first packaging member 281, the second packaging member 282, the third packaging member 283, and the fourth packaging member 284 can be in contact with each other on the edges of the display panel 120 and the cover shield 260.

Meanwhile, referring to FIG. 16, the first fastening portions 281A, 282A, 283A, and 284A of the plurality of packaging members 280 can be inserted to a second fastening portion 260A of the cover shield 260 to be deeper than those in the first state.

The fixing plate FP can be in contact with the magnetic unit MU in the second state. As a result, the fixing plate FP can fix the first packaging member 281 and the second packaging member 282 to the magnetic unit MU. Since the fixing plate FP is in contact with the magnetic unit MU, the fixing plate FP can be fixed to the magnetic unit MU by the magnetic property of the magnetic unit MU to be stronger than in the first state.

In the display device 200 according to another exemplary embodiment of the present disclosure, the packaging member 280 for protecting the display panel 120 can be assembled when conveying the display device. At an installation place for installing the display devices 200 to a tiling display device 200, the packaging member 280 can be separated from the display device 200 and the safely conveyed display device 200 can be assembled to the tiling display device 200. Accordingly, in the display device 200 according to another exemplary embodiment of the present disclosure, when conveying the plurality of display devices 200 for tiling, it is possible to suppress the display device 200 from being damaged due to impact applied to the display panel 120.

In addition, in the display device 200 according to another exemplary embodiment of the present disclosure, the packaging member 280 for packing the display device 200 can be easily separated during conveying of the display device 200. Specifically, since the fixing plate FP is fixed using the magnetic unit MU, the fixing plate FP can be easily separated from the magnetic unit MU by applying the external magnetic force to the magnetic unit MU and the tiling operation and the separating operation can be performed at the same time.

Further, in the display device 200 according to another exemplary embodiment of the present disclosure, in the second state as the state for tiling, the packaging member 280 is not removed, but can be disposed below the display panel 120. Thus, when the user views the display panel 120 on the upper surface side of the display panel 120, the packaging member 280 may not be viewed. Accordingly, in the display device 200 according to another exemplary embodiment of the present disclosure, in the tiling process, while the packaging member 280 is not removed but disposed on the rear surface of the display panel 120, the display device 200 can be tiled. After the tiled display device 200 is detached from the wall surface portion WP, the packaging member 280 disposed on the rear surface of the display panel 120 can be used directly to protect the side surface of the display panel 120, thereby using more easily the packaging member 280.

The exemplary embodiments of the present disclosure can also be described as follows:

According to an aspect of the present invention, a display device includes a display panel, a cover shield disposed on a rear surface of the display panel, a magnetic unit disposed on the rear surface of the display panel to have a magnetic property, a first packaging member disposed on a first side surface of the display panel and the cover shield, a second packaging member disposed on a second side surface which is an opposite surface of the first side surface, a third packaging member disposed on a third side surface of the display panel and the cover shield, a fourth packaging member disposed on a fourth side surface which is an opposite surface of the third side surface, and a fixing plate fixing the first packaging member and the second packaging member to the magnetic unit.

The display device can further comprise a frame supporting the display panel. The magnetic unit can be disposed on the frame and exposed to the outside through a hole of the cover shield.

The fixing plate can be fixed to the magnetic unit by the magnetic property of the magnetic unit.

The fixing plate fixed to the magnetic unit can be detached from the magnetic unit by a magnetic force applied from the outside.

The side surfaces of the display panel can be spaced apart from the first packaging member, the second packaging member, the third packaging member, and the fourth packaging member.

The first packaging member, the second packaging member, the third packaging member, and the fourth packaging member can have grooves at positions corresponding to the side surfaces of the display panel.

A diameter of the groove can be larger than a thickness of the display panel.

The side surfaces of the first packaging member and the second packaging member can include inclined protrusions. The side surfaces of the third packaging member and the fourth packaging member can have inclined surfaces corresponding to the protrusions.

The display device can be in one state of a first state in which the first packaging member, the second packaging member, the third packaging member, and the fourth packaging member cover the side surfaces of the display panel; and a second state in which the first packaging member, the second packaging member, the third packaging member, and the fourth packaging member are disposed below the display panel.

The first state, the fixing plate can be spaced apart from the magnetic unit. In the second state, the fixing plate can be in contact with the magnetic unit.

The first packaging member, the second packaging member, the third packaging member, and the fourth packaging member can include upper plates, side plates, and lower plates. The fixing plate can dispose on the lower plate.

The first state, the upper plates of the first packaging member, the second packaging member, the third packaging member, and the fourth packaging member can dispose on the display panel. The side plates of the first packaging member, the second packaging member, the third packaging member, and the fourth packaging member can be spaced apart from the side surfaces of the display panel.

The second state, the upper plates of the first packaging member, the second packaging member, the third packaging member, and the fourth packaging member can be disposed below the display panel. The side plates of the first packaging member, the second packaging member, the third packaging member, and the fourth packaging member can be disposed inside the side surfaces of the display panel or on the same plane.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

1. A display device comprising:
a display panel;
a cover shield disposed on a rear surface of the display panel;
a magnetic unit disposed on the rear surface of the display panel, and having a magnetic property;
a first packaging member disposed on a first side surface of the display panel and the cover shield;
a second packaging member disposed on a second side surface of the display panel, the second side surface being an opposite surface to the first side surface;
a third packaging member disposed on a third side surface of the display panel and the cover shield;
a fourth packaging member disposed on a fourth side surface of the display panel, the fourth side surface being an opposite surface to the third side surface; and
a fixing plate fixing the first packaging member and the second packaging member to the magnetic unit.

2. The display device of claim 1, further comprising:
a frame supporting the display panel,
wherein the magnetic unit is disposed on the frame and exposed to outside through a hole of the cover shield.

3. The display device of claim 1, wherein the fixing plate is fixed to the magnetic unit by the magnetic property of the magnetic unit.

4. The display device of claim 3, wherein the fixing plate fixed to the magnetic unit is detached from the magnetic unit by a magnetic force applied from the outside.

5. The display device of claim 1, wherein the first to fourth side surfaces of the display panel are spaced apart from the first packaging member, the second packaging member, the third packaging member, and the fourth packaging member, respectively.

6. The display device of claim 5, wherein the first packaging member, the second packaging member, the third packaging member, and the fourth packaging member have grooves at positions corresponding respectively to the first to fourth side surfaces of the display panel.

7. The display device of claim 6, wherein a diameter of at least one of the grooves is larger than a thickness of the display panel.

8. The display device of claim 1, wherein the-side surfaces of the first packaging member and the second packaging member include inclined protrusions, and
side surfaces of the third packaging member and the fourth packaging member have inclined surfaces corresponding to the protrusions.

9. The display device of claim 1, wherein the display device is in one of the following states:
a first state in which the first packaging member, the second packaging member, the third packaging member, and the fourth packaging member cover the first to fourth side surfaces of the display panel; and
a second state in which the first packaging member, the second packaging member, the third packaging member, and the fourth packaging member are disposed below the display panel.

10. The display device of claim 9, wherein in the first state, the fixing plate is spaced apart from the magnetic unit, and
in the second state, the fixing plate is in contact with the magnetic unit.

11. The display device of claim 9, wherein the first packaging member, the second packaging member, the third packaging member, and the fourth packaging member include upper plates, side plates, and lower plates, and
the fixing plate is disposed on the lower plates.

12. The display device of claim 11, wherein in the first state, the upper plates of the first packaging member, the second packaging member, the third packaging member, and the fourth packaging member are disposed on the display panel, and
the side plates of the first packaging member, the second packaging member, the third packaging member, and the fourth packaging member are spaced apart from the first to fourth side surfaces of the display panel.

13. The display device of claim 11, wherein in the second state, the upper plates of the first packaging member, the second packaging member, the third packaging member, and the fourth packaging member are disposed below the display panel, and
the side plates of the first packaging member, the second packaging member, the third packaging member, and the fourth packaging member are disposed inside the first to fourth side surfaces of the display panel or on a same plane.

14. The display device of claim 1, wherein the magnetic unit includes a panel magnet and a panel ferromagnetic material.
